(19) United States
(12) Patent Application Publication
(10) Pub. No.: US 2012/0160152 A1
(43) Pub. Date: Jun. 28, 2012

(54) METHOD FOR CRYSTALLIZING A LAYER

(75) Inventor: Cyril Cayron, Grenoble (FR)

(73) Assignee: Commissariat A L'Energie Atomique Et Aux Energies Alternatives, Paris (FR)

(21) Appl. No.: 13/394,274

(22) PCT Filed: Sep. 14, 2010
(86) PCT No.: PCT/EP2010/063456

§ 371 Date: Mar. 5, 2012

(30) Foreign Application Priority Data
Sep. 14, 2009 (FR) 09 56301

(51) Int. Cl. C30B 1/02; C30B 1/12

(52) U.S. Cl. 117/8; 117/9

(57) ABSTRACT

The transfer of the structure of a crystal (3) having an amorphous or crystal structure to a thin layer (1) with a different structure can be achieved by the combination of a pressing (6) and a heating (7) to apply the layer onto the crystal and anneal it to crystallize it. Characteristically, wedges (5) are placed at the edges to flex the layer and give rise to cracking of the assembly and releasing the layer when the pressure ceases, which eliminates the complicated methods for withdrawing the crystal (3) or even destroying it, enables the use of the crystal (3) in several layers to be crystallized, allows a good manufacturing rate and reduces costs.

This invention relates to a method for crystallizing a layer. It can in particular be concerned with silicon thin layers found in solar heat receivers and microelectronic circuits.

The crystal structure of the layer is not unimportant for these applications: grain boundaries have generally a detrimental influence by absorbing electrical charge carriers and by thus decreasing the efficiency of the device. Generally, it is attempted to obtain coarse-grained crystal structures or even single crystal structures, which is directly impossible with usual manufacturing methods where layers are deposited, whereas other methods, characterised by cutting of layers in crystal blocks having the desired crystal structure, are often too expensive to be considered.

It is however known that crystallizations of the layer accompanied with the coarsening of the grains can be caused by a temperature rise enabling the crystal to be annealed. These crystallizations are often associated with applying to a layer a seed crystal having the crystal structure one wants to assign to it, and which is gradually imposed to the layer as the heat treatment proceeds. In the case of an originally amorphous or low crystal silicon layer, the following have been proposed: aluminium induced crystallizations between 200° C. and 400° C., solid phase crystallizations between 550° C. and 800° C., rapid thermal annealings under a lamp between 700° C. and 1200° C., laser crystallizations between 1200° C. and 1500° C. and zone melting crystallizations between 1200° C. and 1500° C., all of these methods being performed without structure transfer of a seed crystal. Structure transfer techniques of a seed crystal are described in “Future of crystalline silicon films on foreign substrates”, by Bergmann et Werner, published in Thin Solid films 403-404 (2002), pages 162-169; and other—similar techniques—in the article of Tüzün et al. “B-type polycrystalline silicon films formed on aluminium by aluminium induced crystallisation and overdoping”, Thin solid Films, Elsevier—Sequoia SA, Lausanne, vol. 516, n°20, Aug. 30, 2008, pages 6892-6895. The seed generally forms an entire layer, on which the layer to be crystallized is applied or made by deposition, and it is generally attempted to separate it from the crystallized layer after the heat treatment, to use it again with another layer to be crystallized or because it would not be suitable in the finish product; but the usual mechanical methods are difficult to implement to properly separate the seed from the layer, without destructing their junction. The object of the invention is to provide a method for crystallizing a layer by crystal structure transfer which rather enables the layer and the seed crystal to be well separated, which can be used again thereafter for other layers to be crystallized, which improves the manufacture of a series and reduces times and costs.

Moreover, US-A-2005/188917 describes a method for crystallizing a plate by applying a crystal on its surface, without using wedge means to peel it off thereafter.

In a general form, the invention thus relates to a method for crystallizing a layer, comprising applying on the layer a crystal formed from the material of the layer and having a desired crystal structure for the layer, and heat treating the layer in order to introduce the structure of the crystal therein, characterised in that the application is produced by mechanically pressing the layer or a substrate of the layer, after wedges have been fitted at edges of the layer between the layer and the crystal, thereby producing a flexion of the layer.

The pressure application of the layer onto the crystal establishes a close bonding between them, analogous to welding or gluing; but when the pressure is released, the flexion stresses due to the wedges tend to separate the layer from the crystal and produce cracking at the junction thereof.

A separating layer is very advantageously fitted between the layer to be crystallized and the crystal. It is much thinner than the layer to be crystallized and thinner than the wedges, and it extends in a region surrounded by the wedges, where the layer to be crystallized is truly applied to the crystal. It is a fragile region of the assembly, which promotes cracking when the pressure has been released. This is readily obtained if the separating layer is discontinuous, or if it is of a different material from that of the crystal and the layer, or both.

The invention will now be described in more detail in connection with the figures wherein:

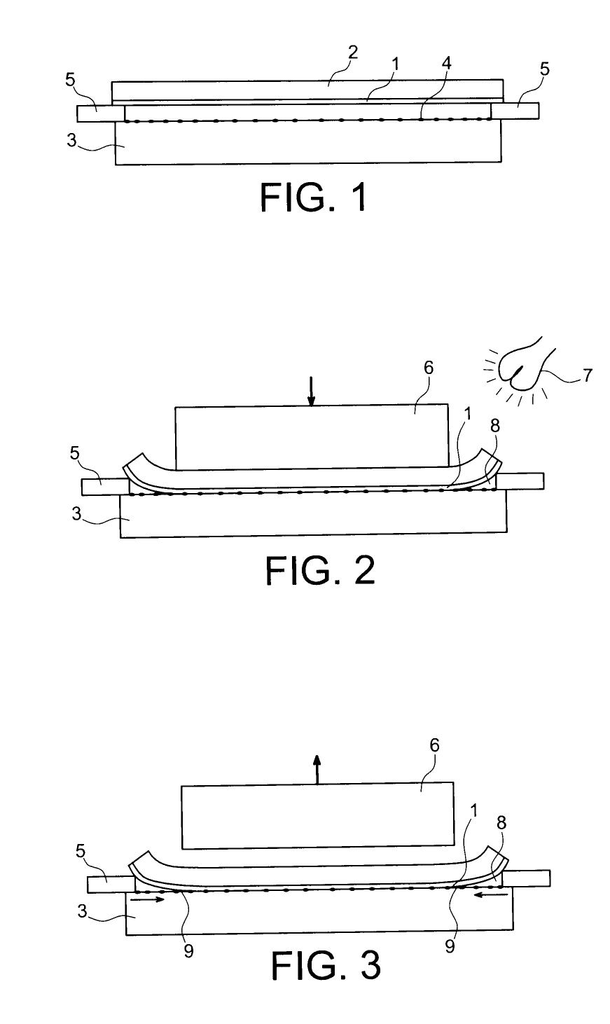

FIG. 1 represents the assembly prior to application of the pressure,

FIG. 2 represents the assembly during the application of the pressure,

and FIG. 3 represents the assembly when the pressure is released.

A layer 1 to be crystallized is placed above a crystal 3 which must impose its crystal structure to it. The layer 1 is thin and has been deposited onto a substrate 2 which provides a support thereof; its thickness can, by way of example, be of about 100 nm or about 2 to 10 μm, preferably 2 μm, for initially amorphous silicon layers intended for microelectronic devices and solar cells respectively. The crystal 3 carries a very thin layer 4. The layer 1 can be of amorphous, microcrystalline or polycrystalline silicon with fine grains, with or without elements decreasing the crystallization temperature (aluminium, gold, copper, silver or palladium, for example for silicon), the crystal 3 is of coarse-grained crystal silicon or single crystal silicone, and the layer 4 is of a refractory material such as silicon carbide, silica, alumina or even porous silicon. Its thickness is a few nanometres or tenths of nanometres. The areas facing the layer 1 and the crystal 3 can be several tens or several hundred square centimetres. Wedges 5 are fitted between the edge regions of the layer 1 and the crystal 3; they are of a refractory material and rather thin, having by way of example a thickness of a few tens of microns in the case of glass substrates 2 (more generally of about 100 μm to 2 mm, about 1 to 2 mm in the case of steel substrates 2). If steel is selected, the Invar type (trademark) can be preferred with a barrier layer to iron and other elements (titanium, vanadium and zirconium) likely to diffuse in the silicon destroying its microelectronic properties. The contacting faces are advantageously polished to improve the contact, or even stripped, for example using HF, to deoxide them and thus not to prevent the crystallization.

FIG. 2 illustrates the application of the layer 1 onto the crystal 3 by a press 6, while a heating means 7 raises the temperature of the assembly. The pressure applied can be in the order of about 500 Pa to 5 MPa, without being limited thereto, and the temperature can be higher than 500° C. A high temperature is preferable, but the substrate 2 in particular restricts it: the glass is no longer solid at about 650° C., and the barrier layers to steel are no longer efficient at about 800° C. A temperature close to the alteration temperature of the substrate 2 will thus be preferred. In the absence of such limits as regards an alteration temperature of the substrate 2 as an essential property, it can be contemplated to heat the material to be crystallized under the melting temperature, that is 1300° C. for silicon. The crystal 3 gradually imposes its structure to the layer 1 to this temperature, either through the discontinuities of the layer 4, or through the solid parts of the layer 4 if it is porous and into a material identical to that of the layer 1. The annealing heat treatment lasts until the crystallization of the layer 1 is achieved, according to a criterion decided by the operator. It is thereby possible to decide that a sufficient crystallization has been achieved when an indexing higher than 65% (more generally 60% to 70%) has been achieved in a mapping by electron backscattered diffraction (EBSD property). The peripheral regions 8, which cannot touch the crystal 3 because of the wedges 5, are an exception and correspond to dead areas of the method, but their width is low, of a few millimetres. It is to be noted that the heating can start before applying the pressure for particularly fragile products.

When the pressure is released, the state represented in FIG. 3 is obtained, where a crack 9 appears between the layer 1 and the crystal 3 from peripheral regions 8 and is propagated towards the centre of the assembly until it causes a full detachment. The crack 9 can also appear upon interrupting the heating without the contribution of an interruption of the application pressure, because of shears which appear at the boundaries of the porous layer 4, the expansion coefficient of which is different from that of the layer 1 and thus produces differential thermal expansions. When the layer 1 has been released, it is possible to grind its surface by a fine polishing, that can be lower than 0.1 μm. Colloidal wax based solutions (Chemical Mechanical Polishing) can be employed. The conditions to make the crack appear are readily met if the substrate 2 has a sufficient elasticity to produce the required shear by straightening up. Silicon and other analogous materials are besides sufficiently fragile to allow a cracking progression.

1. A method for crystallizing a layer, comprising contacting a layer with a crystal, wherein the layer and the crystal comprise an identical material, and heat treating the layer in order to introduce the structure of the crystal therein,
wherein the contacting is performed by mechanically pressing the layer or a substrate of the layer, after wedges have been fitted at edges of the layer between the layer and the crystal, thereby producing a flexion of the layer.

2. The method of claim 1, wherein a separating layer, thinner than the wedges, is disposed between the layer and the crystal in a region surrounded by the wedges, the separating layer being discontinuous.

3. The method of claim 2, wherein the separating layer comprises a material different from that of the crystal and the layer.

4. The method of claim 1, wherein the mechanically pressing is performed at a pressure of 500 Pa to 5 MPa.

5. The method of claim 1, wherein the wedges have a thickness of 100 μm and to 2 mm when the substrate comprises glass, or the wedges have a thickness of 1 mm to 2 mm when the substrate comprises steel.

6. The method of claim 1, wherein the heat treating is a heating performed at a temperature close to an alteration temperature of the substrate.

7. The method of claim 1, further comprising a deoxidation stripping of the crystal, the layer, or of both, before the contacting.

8. The method of claim 1, wherein, prior to the contacting, the layer is amorphous, microcrystalline or polycrystalline silicon with fine grains.

9. The method of claim 1, wherein, prior to the contacting, the crystal is coarse-grained crystal silicon or single crystal silicon.

10. The method of claim 2, wherein the separating layer comprises silicon carbide, silica, alumina or porous silicon.

11. The method of claim 1, wherein the contacting is performed by mechanically pressing a substrate of the layer.

12. The method of claim 11, wherein the wedges have a thickness of 100 μm to 2 mm when the substrate comprises glass, or the wedges have a thickness of 1 mm to 2 mm when the substrate comprises steel.

13. The method of claim 11, wherein the substrate comprises glass, and the heat treating is performed at a temperature not exceeding 650° C.

14. The method of claim 12, wherein the substrate comprises steel, and the heat treating is performed at a temperature not exceeding 800° C.

15. The method of claim 13, wherein the wedges have a thickness of 100 μm to 2 mm.

16. The method of claim 14, wherein the wedges have a thickness of 1 mm to 2 mm.

17. The method of claim 1, wherein the heat treating is performed until an indexing higher than 65% has been achieved in a mapping by electron backscattered diffraction.

18. The method of claim 8, wherein the layer further comprises at least one element selected from the group consisting of aluminum, gold, copper, silver and palladium.

19. The method of claim 1, further comprising ending the mechanical pressing and propagating a crack between the layer and the crystal, to obtain a released crystallized layer.

20. The method of claim 1, further comprising interrupting the heating and propagating a crack between the layer and the crystal, to obtain a released crystallized layer.
